(19) United States
(12) Patent Application Publication
(10) Pub. No.: US 2025/0311121 A1
(43) Pub. Date: Oct. 2, 2025

(54) ELECTRICAL PART COOLING STRUCTURE

(71) Applicant: HONDA MOTOR CO., LTD., Tokyo (JP)

(72) Inventor: Ryoma HAMASUNA, Wako-shi (JP)

(21) Appl. No.: 19/063,520

(22) Filed: Feb. 26, 2025

(30) Foreign Application Priority Data
Mar. 29, 2024 (JP) 2024-057950

(51) Int. Cl. H05K 5/02; H05K 7/20

(52) U.S. Cl. CPC H05K 5/02; H05K 7/20272

(57) ABSTRACT

An electrical part cooling structure includes a container that receives a capacitor that produces heat while energized, and a housing that is provided with the container. The housing includes a bottom wall that includes a refrigerant circulation part recessed outward of the housing from the bottom wall of the housing, and a hole portion through which a refrigerant that has entered the housing is discharged. The container includes a bottom wall that includes an annular convex part fitted in the refrigerant circulation part, a refrigerant discharge groove that communicates with the hole portion outside of the annular convex part, and a fixing part fixed on the housing outside of the refrigerant discharge groove. The refrigerant circulation part has an inner periphery that defines a first groove that receives a first sealing member.

### CROSS-REFERENCE TO RELATED APPLICATIONS

The present application claims the priority under 35 U.S.C. § 119 of Japanese Patent Application No. 2024-057950, filed on Mar. 29, 2024, the contents of which are hereby incorporated by reference in its entirety.

### BACKGROUND OF THE DISCLOSURE

### 1. Field of the Disclosure

The present disclosure relates to an electrical part cooling structure using a refrigerant.

### 2. Description of the Related Art

Patent Literature 1 (Japanese Patent No. 6,236,904) describes a power conversion device including a main circuit container receiving a main circuit and a capacitor container receiving capacitors. The main circuit container includes a base plate provided with the main circuit and a cover that covers the main circuit. The capacitor container is disposed on a surface opposite to the main circuit of the base plate so as to seal an opening of the capacitor container. Further, the base plate includes a refrigerant channel therein in which a refrigerant that cools the main circuit circulates.

In this structure, the refrigerant channel mainly aims to cool the main circuit. When a cooling performance for the capacitors is desired to be improved, as a solution, the capacitor container is received in the main circuit container, and a wall portion of the main circuit container is combined with a wall portion of the capacitor container to provide the refrigerant channel between the wall portions. However, this structure may cause the refrigerant to enter the main circuit container from gaps between the wall portions.

The present disclosure has been made in view of the above issue and aims to provide an electrical part cooling structure capable of improving a cooling performance for electrical parts while preventing a refrigerant from entering a housing, and appropriately discharging the refrigerant that has entered the housing to an outside of the housing.

To solve the above issue, an electrical part cooling structure of the present disclosure includes an electrical part that produces heat while energized, a container that receives the electrical part and includes a wall portion, and a housing that is provided with the container and includes a wall portion. The wall portion of the housing includes a refrigerant circulation part that is recessed outward of the housing from the wall portion of the housing and in which a refrigerant circulates, and a hole portion through which the refrigerant that has entered the housing is discharged. The wall portion of the container includes an annular convex part fitted in the refrigerant circulation part, a refrigerant discharge groove formed to communicate with the hole portion outside of the annular convex part, and a fixing part fixed on the housing outside of the refrigerant discharge groove. At least one of an inner periphery of the refrigerant circulation part and an outer periphery of the annular convex part has a first groove that receives a first sealing member to seal a gap between the refrigerant circulation part and the annular convex part.

According to the present disclosure, the electrical part cooling structure is capable of improving the cooling performance for the electrical parts while preventing the refrigerant from entering the housing, and appropriately discharging the refrigerant that has entered the housing to the outside of the housing.

### BRIEF DESCRIPTION OF DRAWINGS

FIG. 1 is a perspective view schematically showing a voltage booster with an electrical part cooling structure according to an embodiment of the present disclosure.

FIG. 2 is a perspective view schematically showing a capacitor unit according to the embodiment of the present disclosure.

FIG. 3 is a plan view schematically showing the capacitor unit according to the embodiment of the present disclosure.

FIG. 4 is a side view schematically showing the capacitor unit according to the embodiment of the present disclosure.

FIG. 5 is a bottom view schematically showing the capacitor unit according to the embodiment of the present disclosure.

FIG. 6 is a perspective view schematically showing an assembled body of a capacitor, a holding member, and a bus-bar according to the embodiment of the present disclosure.

FIG. 7 is a perspective view schematically showing a container according to the embodiment of the present disclosure.

FIG. 8 is a front view schematically showing the container according to the embodiment of the present disclosure.

FIG. 9 is a perspective view schematically showing the capacitor unit without a resin part according to the embodiment of the present disclosure.

FIG. 10 is a front view schematically showing the capacitor unit without a resin part according to the embodiment of the present disclosure.

FIG. 11 is a cross-sectional view taken along an XI-XI line of FIG. 1, schematically showing the electrical part cooling structure according to the embodiment of the present disclosure.

FIG. 12 is a partially enlarged view of FIG. 1

### EMBODIMENTS OF THE DISCLOSURE

Next, in embodiments of the present disclosure, electrical part cooling structures will be described in detail with reference to drawings as appropriate, with a case of cooling electrical parts that constitute a voltage booster (Voltage Control Unit or VCU) of a vehicle as an example. A vehicle to which the electrical part cooling structure of the present disclosure is applied includes electric-powered cars (an electric vehicle) powered by a motor, and electrical parts to which the electrical part cooling structure is applied include a capacitor.

In the descriptions below, a vertical direction (a top-bottom direction) is based on the voltage booster being mounted on the vehicle. A longitudinal direction (a front-rear direction) and a lateral direction (a right-left direction) that are orthogonal to the vertical direction are based on a container that receives capacitors. The longitudinal direction is a direction of a depth of the container and the lateral direction is a direction of a width of the container. In other words, the longitudinal direction and the lateral direction of the present embodiments do not necessarily coincide with a front-rear direction and a right-left direction of a vehicle.

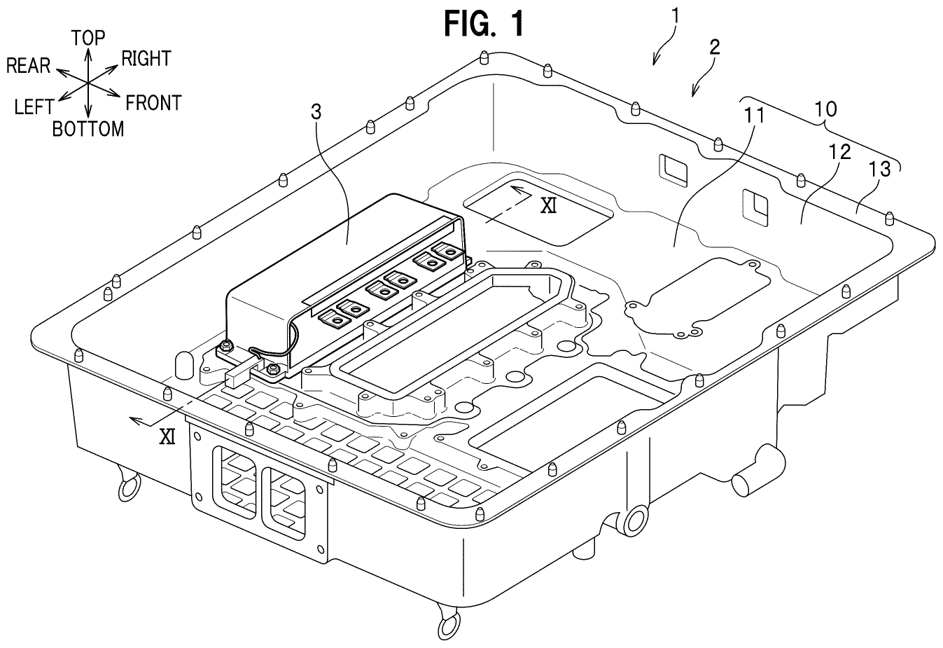

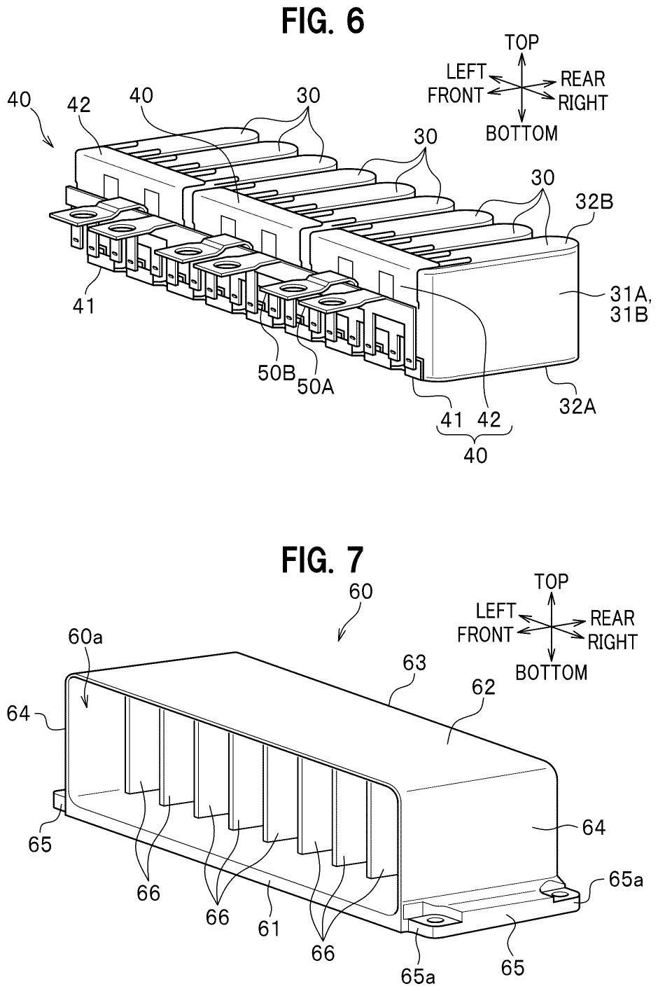

As shown in FIG. 1, an electrical part cooling structure 1 of the embodiment of the present disclosure is capable of cooling capacitors 30, shown in FIG. 6, as an electrical part that constitutes a circuit of a voltage booster 2 mounted on a vehicle. In FIG. 1, electrical parts (an electrical part unit) except the capacitor 30 are not shown. The voltage booster 2 is disposed between a battery and a motor of the vehicle. The voltage booster 2 boosts a battery voltage up to a voltage required for the motor, and provides the motor with the boosted battery power. The voltage booster 2 to which the electrical part cooling structure 1 is applied includes a housing 10, a first sealing member 20A (see FIG. 5), a second sealing member 20B (see FIG. 5), and a capacitor unit 3.

### <Housing>

The housing 10 is a metallic member to receive the electrical parts constituting the voltage booster 2. The electrical parts received in the housing 10 include the capacitor 30 (see FIG. 6), a reactor, an inverter, and a converter.

The housing 10 has an open upper portion, and includes, as a single part, a bottom wall 11, a lateral wall 12 standing upward from the bottom wall 11, and an annular (rectangular shaped) flange 13 extending outward from an upper end of the lateral wall 12.

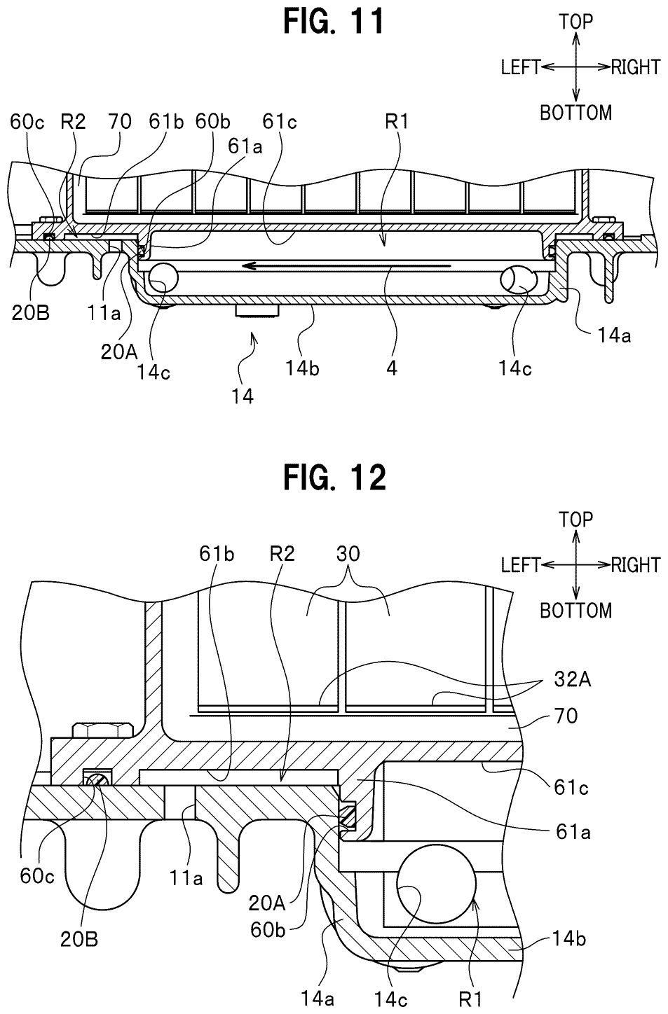

The bottom wall 11 is formed with a refrigerant circulation part 14 (see FIG. 11) recessed outward (downward in this embodiment) from the housing 10, which will be described in detail later.

The flange 13 is fixed on a lower end of another device of the vehicle (a power module, for example) of the vehicle using a part such as a bolt.

### <First and Second Sealing Members>

The first sealing member 20A and the second sealing member 20B (see FIG. 5) are annular (substantially rectangular shaped) resin members (gaskets) that seal gaps between the housing 10 and a container 60 of the capacitor unit 3. Assembly of the first sealing member 20A and the second sealing member 20B will be described in detail later.

### <Capacitor Unit>

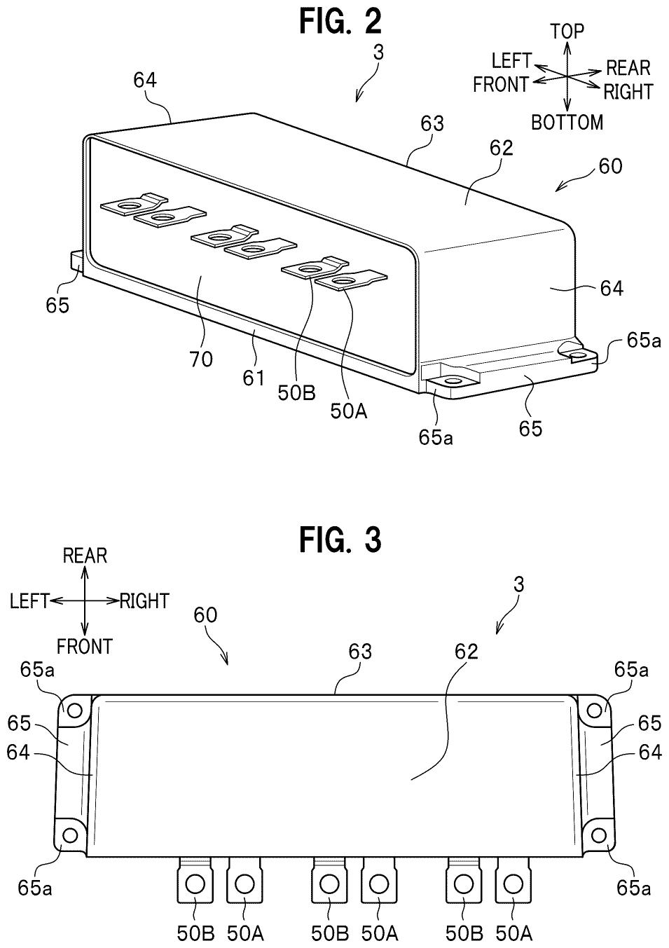

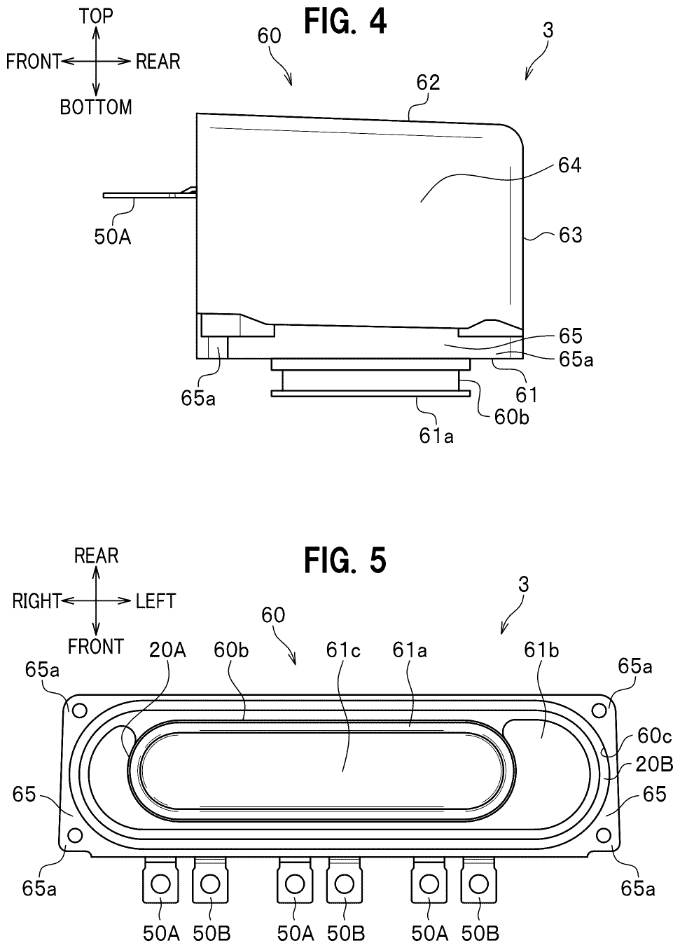

As shown in FIGS. 2 through 5, the capacitor unit 3 includes a plurality of the capacitors 30 (see FIG. 6), a holding member 40 (see FIG. 6), bus-bars 50A, 50B, the container 60, and a resin part 70.

### <Capacitor>

As shown in FIG. 6, each capacitor 30 is an electrical part (an electrical element) that produces heat while energized, and includes two metalized films 31A, 31B on which electrodes are formed on a dielectric film and metal-sprayed electrodes 32A, 32B as external electrodes. The two metalized films 31A, 31B are overlapped with each other and wound around an axis of the capacitor 30 (around a vertical axis in the present embodiment). The metal-sprayed electrode 32A is the external electrode (an N electrode in the present embodiment) formed on one end (a lower end in the present embodiment) in an axial direction of the wound metalized films 31A, 31B. The metal-sprayed electrode 32A is joined to the metalized films 31A, 31B and electrically connected to the electrode of the metalized film 31A. The metal-sprayed electrode 32B is the external electrode (a P electrode in the present embodiment) formed on the other axial end (an upper end in the present embodiment) in the axial direction of the wound metalized films 31A, 31B. The metal-sprayed electrode 32B is joined to the metalized films 31A, 31B and electrically connected to the electrode of the metalized film 31B.

### <Holding Member>

The holding member 40 is a metallic or resin member that holds a plurality of the capacitors 30 (three, in the present embodiment). In the present embodiment, the holding member 40 includes a lower holding member 41 that holds lower parts of the capacitors 30 and an upper holding member 42 that holds upper parts of the capacitors 30.

### <Bus-Bar>

The bus-bar 50A is a metallic member that electrically connects the metal-sprayed electrodes 32A of the capacitors 30 to the other electrical parts of the voltage booster 2. The bus-bar 50A has one end that connects a plurality of the metal-sprayed electrodes 32A of the capacitors 30 (nine, in the present embodiment) in parallel via a lead terminal (not shown). The bus-bar 50A has the other end that is exposed from the container 60 and the resin part 70, which will be described later, and electrically connected to the other electrical parts of the voltage booster 2.

The bus-bar 50B is a metallic member that electrically connects the metal-sprayed electrodes 32B of the capacitors 30 to the other electrical parts of the voltage booster 2. The bus-bar has one end that connects a plurality of the metal-sprayed electrodes 32B of the capacitors 30 (nine, in the present embodiment) in parallel via a lead terminal (not shown). The bus-bar 50B has the other end that is exposed from the container 60 and the resin part 70, which will be described later, and electrically connected to the other electrical parts of the voltage booster 2.

### <Arrangement of Capacitors>

A plurality of the capacitors 30 are arranged such that the metal-sprayed electrodes on the one ends in the axial direction of capacitors 30 face in the same direction (a downward direction, in the present embodiment) and arranged in a row in a direction crossing (orthogonal to) the axial direction (a direction parallel to a surface of the metal-sprayed electrode 32A, or the lateral direction in the present embodiment) of the capacitor 30. The neighboring capacitors 30, 30 are spaced apart at regular intervals.

### <Container>

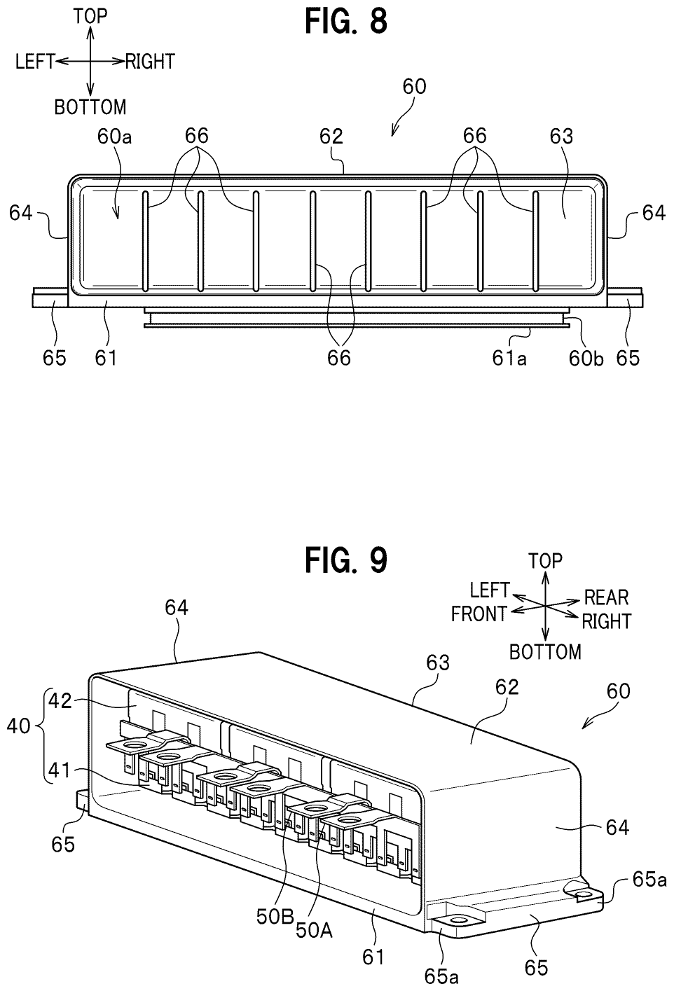

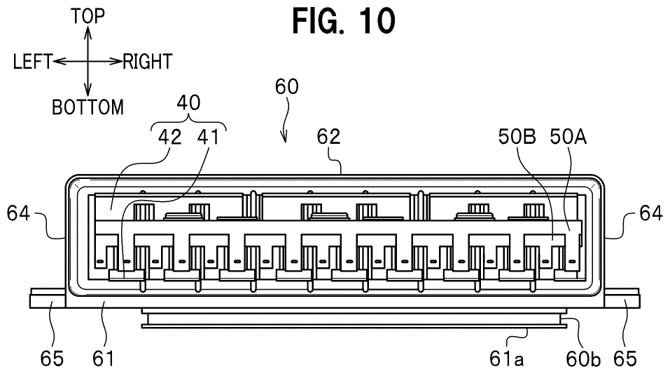

As shown in FIGS. 2 through 5, the container 60 is a metallic member (such as aluminum) that receives a plurality of the capacitors 30. As shown in FIGS. 7 and 8, the container 60 includes, as a single part, a bottom wall 61, a top wall 62 facing the bottom wall 61, a back wall 63 connecting peripheral edges of the bottom wall 61 and the top wall 61 to each other, and a pair of side walls 64, 64. The container 60 further includes a pair of flange 65, 65 that extends from both ends of the bottom wall 61 beyond the side walls 64. The container 60 further includes a plurality of ribs 66 that divide internal space of the container 60. The container 60 has a front end formed with an opening 60a.

The flange 65 is a part of the bottom wall 61. The flange 65 has end portions in the longitudinal direction, which are fixing portions 65a, 65a fixed on the bottom wall 11 of the housing 10 with parts such as bolts. The fixing portion 65a is formed outside a refrigerant discharge groove 61b, which will be described later.

A plurality of the ribs 66 (six, in the present embodiment) are arranged between a pair of the side walls 64, 64 at regular intervals and laterally divide the internal space of the container 60 into multiple spaces. Each rib 66 has a lower end joined to the bottom wall 61, an upper end joined to the top wall 62, and a back end (a rear end) joined to the back wall 63. A longitudinal dimension of each rib 66 is smaller than that of the bottom wall 61 and the top wall 62. Each rib 66 intervenes between the neighboring capacitors 30, 30. In other words, the capacitors 30 are received in the spaces divided by the ribs 66 in the container 60 respectively.

As shown in FIG. 5, the bottom wall 61 has an outer surface (a lower surface, in the present embodiment) formed with an annular convex part 61a and the refrigerant discharge groove 61b.

The annular convex part 61a protrudes downward from the lower surface of the bottom wall 61. The bottom wall 61 has a region that is surrounded by the annular convex part 61a and the region constitutes a refrigerant circulation part 61c.

The refrigerant discharge groove 61b is formed outside the annular convex part 61a and inside the fixing part 65a, and recessed upward from the lower surface of the bottom wall 61. The refrigerant discharge groove 61b is formed continuously with portions of the annular convex part 61a which are close to a pair of the side walls 64, 64 and the opening 60a.

As shown in FIGS. 11 and 12, the annular convex part 61a of the bottom wall 61 and a pair of the flange 65, 65 are formed with a first groove 60b and a second groove 60c.

The first groove 60b is formed on an outer peripheral surface of the annular convex part 61a.

The second groove 60c is formed on the lower surface of the bottom wall 61 and a pair of the flange 65, 65. The second groove 60c is annularly formed so as to surround the annular convex part 61a and the refrigerant discharge groove 61a from the outside of the container 60 in the axial direction thereof.

### <Resin Part>

The resin part 70 is a solidified resin (an epoxy resin, for example) that is filled in the container 60 to cover the capacitors 30, the holding member 40, and the bus-bars 50A, 50B that are received in the container 60. The resin part 70 prevents capacitors 30 from contacting the refrigerant 4 (see FIGS. 1 and 12).

### <Refrigerant Circulation Structure>

The refrigerant circulation part 14 formed on the bottom wall 11 of the housing 10 includes, as a single part, a peripheral wall 14a that extends from the bottom wall 11 outward of the housing 10 (downward, in the present embodiment) and an end wall 14b that is fitted to a distal end (a lower end, in the present embodiment) of the peripheral wall 14a. The peripheral wall 14a has end portions in the lateral direction, which are formed with hole portions 14c, 14c, respectively as an inlet and an outlet for the refrigerant 4.

The container 60 is fixed, at the fixing part 65a thereof, on the bottom wall 11 of the housing 10 with a bolt. Under the container 60 being fixed, the annular convex part 61a is fitted or inwardly fitted in the peripheral wall 14a of the refrigerant circulation part 14. In other words, the annular convex part 61a and the refrigerant circulation part 61c constitute a refrigerant channel R1 in which the refrigerant 4 circulates in cooperation with the refrigerant circulation part 14 (the peripheral wall 14a and the end wall 14b). Further, the fitted portion is sealed by a first sealing member 20A received in the first groove 60b to prevent the refrigerant 4 from passing through the engaged portion.

The first sealing member 20A is received in the first groove 60b with a portion protruding from the first groove 60b before the housing 10 and the container 60 assembled together. With the first sealing member 20A being pressed in the gap between the annular convex part 61a and the peripheral wall 14a, the first sealing member 20A functions as an axial seal between the annular convex part 61a and the peripheral wall 14a in the axial direction of the container 60.

Outside the refrigerant channel R1, the refrigerant discharge groove 61b faces the bottom wall 11 while communicating with the hole portion 11a formed on the bottom wall 11. The hole portion 11a is a hole from which the refrigerant 4 that has entered the housing 10 is discharged outside the housing 10. In other words, the refrigerant discharge groove 61b constitutes a refrigerant discharge channel R2 from which the refrigerant 4 is discharged in cooperation with the bottom wall 11.

Outside the refrigerant discharge channel R2, the bottom wall 61 and the flange 65 contact the bottom wall 11. The contact portion is sealed by the second sealing member 20B received in the second groove 60c to prevent the refrigerant 4 from passing through the contact portion.

The second sealing member 20B is received in the second groove 60c with a portion protruding from the second groove 60c before the housing 10 and the container 60 assembled together. With the second sealing member 20B being pressed into the gap between the bottom surface of the second groove 60c and the bottom wall 11, the second sealing member 20B functions as a surface seal between the bottom wall 61 and the bottom wall 11 in a surface direction orthogonal to the axial direction of the container 60.

The electrical part cooling structure 1 uses the first sealing member 20A as an axial seal and the second sealing member 20B as a surface seal. This reduces fixing points of the electrical parts (the capacitors 30 and the capacitor unit 3) to the housing 10 in comparison to a configuration using two surface seals, thereby simplifying the structure. Further, the electrical part cooling structure 1 shortens a distance between the capacitor 30 and external devices (a power module, for example) in comparison to a configuration using two axial seals, thereby reducing a parasitic inductance.

In this structure, the refrigerant 4 circulating in the refrigerant channel R1 exchanges heat with the metal-sprayed electrode 32A via the bottom wall 61 to absorb and release heat produced in the capacitor 30 that is then cooled. The conduction efficiency of heat produced in the metalized films 31A, 31B of the capacitor 30 is better in a direction of an axis wound by the metalized films 31A, 31B (vertical direction, in the present embodiment) than in an orthogonal direction to the axis direction.

The heat produced in the metalized films 31A, 31B is transferred to the metal-sprayed electrode 32A, and then transferred to the refrigerant 4 via bottom wall 61 that is positioned near the metal-sprayed electrode 32A and faces the metal-sprayed electrode 32A with the intervening the resin part 70. In other words, the metal-sprayed electrode 32A is provided proximate to the bottom wall 61, and the capacitor 30 is appropriately cooled by the refrigerant 4.

The heat produced in the metalized films 31A, 31B is partially transferred to the metal-sprayed electrode 32B, then transferred to the bottom wall 61 via any of the back wall 63, the side wall 64, or the rib 66 from the top wall 62 that is positioned near the metal-sprayed electrode 32B and faces the metal-sprayed electrode 32B via the resin part 70, and then transferred to the refrigerant 4 via the bottom wall 61. In other words, the metal-sprayed electrode 32B is provided proximate to the top wall 62 joined to the bottom wall 61 via a part such as the rib 66, and the capacitor 30 is appropriately cooled by the refrigerant 4. Note that the heat transferred to the metal-sprayed electrode 32B is partially transferred to atmosphere outside the container 60 from the top wall 62, the back wall 63, and the side wall 64.

The neighboring capacitors 30, 30 are arranged in a direction orthogonal to a direction of arrangement of the metal-sprayed electrodes 32A, 32B. This structure further reduces temperature rise due to heat interference between the neighboring capacitors 30, 30 in comparison to a structure in which the metal-sprayed electrodes 32A, 32B of the neighboring capacitors 30,30 are arranged face-to-face. Further, this structure reduces the distance between the neighboring capacitors 30. 30.

The ribs 66 reduce temperature rise due to heat interference between the neighboring capacitors 30,30 and helps reduce the maximum temperature of the capacitor 30. Further, the ribs 66 improve strength of the container 60, which allows the bottom wall 61 to be thinner, thereby improving a cooling performance for capacitor 30.

### <Structure of Preventing Refrigerant From Entering Housing>

An occurrence of the refrigerant leakage to the outside of the refrigerant channel R1 will be described below. The outside is defined as a location within the housing 10 and beyond the first sealing member 20A in a direction toward a region in which the electrical parts except the capacitor 30 are received. In this leakage occurrence, the refrigerant 4 is discharged outside the housing 10 via the refrigerant discharge channel R2 and the hole portion 11a before entering the region within the housing 10 and outside the refrigerant channel R1. Further, the refrigerant 4 leaked outside the refrigerant channel R1 is prevented from entering the region within the housing 10 and outside the refrigerant channel R1.

The capacitor unit 3 according to the embodiment of the present disclosure includes a plurality of the capacitors 30 that are arranged in a row and each has the metal-sprayed electrode 32A on one end in an axial direction of the capacitor 30, and the container 60 that receives the capacitors 30. The capacitors 30 are arranged in a direction orthogonal to the axial direction of the capacitor 30 with a posture of each metal-sprayed electrode 32A facing in one direction. The container 60 includes the rib 66 intervening between the neighboring two capacitors 30 and the wall portion (the bottom wall 61) that faces the metal-sprayed electrode 32. The wall portion constitutes a part of the channel (the refrigerant channel R1) for the refrigerant 4. This structure allows the capacitor unit 3 to appropriately cools the capacitors 30.

In the capacitor unit 3, the rib 66 is joined to the wall portion. This allows the capacitor unit 3 to appropriately cools the capacitors 30 via the rib 66.

In the capacitor unit 3, the rib 66 is joined to the other wall portion (the top wall 62) of the container 60, which faces the other end in the axial direction of the capacitor 30. This allows the capacitor unit 3 to reduce the thickness of the wall portion to appropriately cool the capacitors 30.

The electrical part cooling structure 1 of the embodiment of the present disclosure includes the electrical part (the capacitor 30) producing heat while energized, the container 60 receiving the electrical part, and the housing 10 on which the container 60 is disposed. The wall portion (the bottom wall 11) of the housing 10 is recessed outward of the housing 10 from the wall portion, and includes the refrigerant circulation part 14 in which the refrigerant 4 circulates and the hole portion 11a through which the refrigerant 4 that has entered the housing 10 is discharged. The wall portion (the bottom wall 61) of the container 60 includes the annular convex part 61a fitted in the refrigerant circulation part 14, the refrigerant discharge groove 61b formed to communicate with the hole portion 11a outside of the annular convex part 61a, and the fixing part 65a fixed on the housing 10 outside of the refrigerant discharge groove 61b. At least one of the inner periphery of the refrigerant circulation part 14 and the outer periphery of the annular convex part 61a has the first groove 60b that receives the first sealing member 20A to seal the gap between the refrigerant circulation part 14 and the annular convex part 61a. Accordingly, the electrical part cooling structure 1 improves cooling efficiency for the electrical parts and appropriately prevents the refrigerant 4 from entering the housing 10 (or being leaked from the refrigerant channel R1), and discharges the refrigerant 4 that has entered the housing 10 (or leaked from the refrigerant channel R1) to the outside of the housing 10.

In the electrical part cooling structure 1, at least one of the wall portion of the housing 10 and the wall portion of the container 60 has the second groove 60c that is positioned between the refrigerant discharge groove 61b and the fixing part 65a and receives the second sealing member 20B to seal the gap between the housing 10 and the container 60. Accordingly, the electrical part cooling structure 1 improves cooling efficiency for the electrical parts and appropriately prevents the refrigerant 4 from entering the housing 10 (or being leaked from the refrigerant channel R1) and discharges the refrigerant 4 that has entered the housing 10 (or leaked from the refrigerant channel R1) to the outside of the housing 10.

While the embodiment of the present disclosure had been described, the present disclosure is not limited to the embodiment described above and various modifications are possible as appropriate without departing from the scope of the disclosure. For example, the electrical part cooling structure 1 and/or the capacitor unit 3 can be applied not only to electrical vehicles but also to heavy machinery or vessels. Further, the first groove 60b that receives the first sealing member 20A can be formed not only on the peripheral wall 14a of the refrigerant circulation groove 14 of the housing 10 but also on both the peripheral wall 14a and the annular convex part 61a. In a similar way, the second groove 60c that receives the second sealing member 20B can be formed not only on the bottom wall 11 of the housing 10 but also on both: the bottom wall 11; and the bottom wall 11 and flange 65.

What is claimed is:

1. An electrical part cooling structure comprising
an electrical part that produces heat while energized,
a container that receives the electrical part and includes a wall portion, and
a housing that is provided with the container and includes a wall portion, wherein
the wall portion of the housing includes
a refrigerant circulation part that is recessed outward of the housing from the wall portion of the housing and in which a refrigerant circulates, and
a hole portion through which the refrigerant that has entered the housing is discharged,
the wall portion of the container includes
an annular convex part fitted in the refrigerant circulation part,
a refrigerant discharge groove formed to communicate with the hole portion outside of the annular convex part, and
a fixing part fixed on the housing outside of the refrigerant discharge groove, and
at least one of an inner periphery of the refrigerant circulation part and an outer periphery of the annular convex part defines a first groove that receives a first sealing member to seal a gap between the refrigerant circulation part and the annular convex part.

2. The electrical part cooling structure according to claim 1, wherein
at least one of the wall portion of the housing and the wall portion of the container defines a second groove that is positioned between the refrigerant discharge groove and the fixing part, wherein the second groove receives a second sealing member which seals a gap between the housing and the container.
